(19) United States
(12) Patent Application Publication
(10) Pub. No.: US 2015/0292085 A1
(43) Pub. Date: Oct. 15, 2015

(54) METHOD FOR PRODUCING A LAYER ON A SURFACE AREA OF AN ELECTRONIC COMPONENT

(71) Applicant: OSRAM OLED GmbH, Regensburg (DE)

(72) Inventors: Richard Baisl, Regensburg (DE); Michael Popp, Freising (DE)

(21) Appl. No.: 14/646,004

(22) PCT Filed: Nov. 18, 2013
(86) PCT No.: PCT/EP2013/074068

§ 371 Date: May 19, 2015

(30) Foreign Application Priority Data
Nov. 19, 2012 (DE) 102012 221 080.6

(51) Int. Cl. C23C 16/455; C23C 16/48; C23C 16/04

(52) U.S. Cl. CPC C23C 16/45525; C23C 16/042; C23C 16/48

(57) ABSTRACT

The invention relates to a method for producing at least one layer (1) on a surface area (2) of an optoelectronic component (100, 101, 102, 103, 104, 105) comprising a functional layer sequence (41) with an active area which is suitable to produce or to detect the light when the optoelectronic component is in operation. Said method consists of the following steps: introducing the surface area (2) into a coating chamber (10); depositing the at least one layer (1) according to a flash-light supported atomic layer deposition method in which the surface area (2) is exposed to at least one gaseous first initial material (21) or at least one gaseous first initial material (21) and subsequently a gaseous second initial material (22) to form the at least one layer (1), and molecules of the first and/or second initial material (21, 22), which are absorbed on the surface area, are exposed to at least one flash of light, the molecules absorbed on the surface area being split.

A method for producing at least one layer on a surface region of an electronic component is specified.

This patent application claims the priority of German patent application 10 2012 221 080.6, the content of the disclosure of which is hereby incorporated by reference.

Optoelectronic components, for example organic light-emitting diodes (OLED) but also inorganic light-emitting diode chips, can be relatively sensitive to moisture, oxygen, and/or other damaging environmental gases.

In particular in the case of OLEDs, protecting the sensitive organic layers by means of a cavity glass and a getter material attached therein is known. Furthermore, sensitive components can also be protected, for example, by means of thin-film encapsulations in the form of barrier layers or nanolaminates, i.e., layer sequences made of alternating layers having different materials. Such thin-film encapsulations can preferably also be used in transparent and/or flexible components. By means of atomic layer deposition (ALD) methods, very thin barrier layers and layers of nanolaminates, for example, down to the thinness of monolayers, may be produced reproducibly.

The concept of atomic layer deposition is known in particular to include those methods in which to produce a layer, the starting materials required for this purpose (precursors) are typically not supplied simultaneously, but rather alternately in succession to a coating chamber in which the component to be coated is arranged. Due to the alternate supply, the starting materials can alternately accumulate one on top of another on the surface of the component to be coated or on a previously accumulated starting material and can form compounds thereon. In this way it is possible to grow at most one monolayer of the layer to be applied per cycle repetition, i.e., the one-time supply of all required starting materials in successive partial steps, so that good control of the layer thickness is possible by way of the number of cycles.

The starting materials are typically provided in chemical compounds, for example, in organometallic compounds or hydrides, which are split by the supply of thermal energy. For this purpose, the component to be coated is heated and can additionally be subjected to a plasma, depending on the ALD method. To prevent damage to the components to be coated, for example, in the case of organic components, the ALD methods must be carried out at a relatively low temperature, which can often be less than 150° C. and in particular can be in the range from room temperature up to 100° C. Since furthermore many known compounds of desired starting materials cannot be split or can only be split with difficulty at the mentioned temperatures, the material selection is restricted accordingly in the case of known ALD methods.

In addition, known ALD methods do not permit masking and are therefore only capable of depositing layers over a large area and in an unstructured manner. The effectiveness of approaches using anti-coating layers has not yet been able to be industrially proven, so that a layer applied by means of ALD typically must be removed in regions by laser ablation for structuring. In particular in the region of the active region of a component, such as an OLED, however, laser ablation is hardly possible.

At least one object of specific embodiments is to specify a method for producing a layer on a surface region of an electronic component.

This object is achieved by a subject matter according to the independent patent claim. Advantageous embodiments and refinements of the subject matter are characterized in the dependent claims and are furthermore disclosed in the following description and the drawings.

According to at least one embodiment, a method for producing at least one layer on a surface region of an electronic component has a method step in which the at least one layer is applied by means of a light-flash-assisted atomic layer deposition method. Such a method can also be referred to hereafter as light flash ALD (ALD: atomic layer deposition) or flash light ALD. For the light flash ALD method, the surface region on which the at least one layer is to be applied can preferably be provided in a coating chamber. The coating chamber can be configured in particular so that light flash ALD can be carried out therein.

In conventional ALD methods, starting materials are successively supplied to a coating chamber, as described above, in which the component to be coated is located. To achieve a high layer quality in conventional ALD methods, for example, with regard to the density, the crystallinity, and the purity, high temperatures are necessary depending on the starting materials used, to which the component to be coated must be heated. As already described above, this significantly restricts the selection of the possible starting materials depending on the heat compatibility of the components to be coated. In the case of the light flash ALD method used here, the energy required for the layer production is provided entirely or in a substantial part by means of at least one light flash. For this purpose, the surface region is subjected to at least one gaseous first starting material for the at least one layer and irradiated using the at least one light flash. The gaseous first starting material can preferably be a gas having molecules which are formed by compounds of a material to be incorporated in the layer, having further atoms and/or molecule groups, for example, hydrogen and/or organic molecule groups. By way of the at least one light flash, which is radiated onto the surface region to be coated of the electronic component in the presence of the first starting material, splitting of the gaseous first starting material can preferably be achieved, so that the material released by the splitting, which is to be incorporated into the at least one layer, can accumulate on the surface region of the electronic component.

The light radiated onto the surface region using the at least one light flash can contain spectral components, for example, which are capable of splitting the gaseous first starting material. In other words, the molecules of the gaseous first starting material can have absorption bands which correspond to one or more spectral components of the light contained in the at least one light flash. Furthermore, it can also be possible that the light radiated onto the surface region using the at least one light flash is absorbed in the surface region of the electronic component and thus heats the latter. For this purpose, the light of the at least one light flash preferably has spectral components which are in the absorption spectrum of the surface region which is to be coated using the at least one layer, and which can therefore be absorbed by the surface region of the electronic component. A part of the electronic component below the surface region to be coated can thus also be heated by heat conduction. By way of a suitable selection of the spectral components, the duration, and the energy of the light flash, however, only a thin layer below the surface region to be coated can be heated by the light flash. For example, visible light is absorbed by silicon in a layer thickness of only a few micrometers. By way of the at least one light flash, only the surface region irradiated with the light flash can be heated in a depth of only a few micrometers, for example, while the remaining electronic component is not heated or at least has a significantly lower temperature than the surface region.

According to a further embodiment, the at least one light flash has a time duration of less than 10 ms, preferably less than 5 ms, and particularly preferably less than 2 ms. For example, the at least one light flash can have a duration of approximately 1 ms. To achieve sufficient heating of the surface region, the light flash can preferably have an energy density of greater than or equal to 1 J/cm² or also greater than or equal to 10 J/cm² or also greater than or equal to 20 J/cm² or also greater than or equal to 40 J/cm². Depending on the absorption properties of the starting material used and/or the surface region to be coated, the light contained in the light flash can comprise, for example, essentially visible light and in particular a fraction of ultraviolet and infrared light which is less than 10%. Furthermore, it can also be advantageous if the light contained in the at least one light flash contains spectral components in the ultraviolet and/or infrared wavelength range in a larger fraction or even only consists of such spectral components.

According to a further embodiment, the at least one light flash is supplied by means of a light source which comprises at least one gas discharge lamp, at least one halogen lamp, at least one laser, in particular at least one laser diode, at least one light-emitting diode (LED), or a plurality thereof. The light source can also comprise or consist of a combination of the mentioned light sources. For example, the light source can comprise one or more xenon gas discharge lamps which typically primarily emit visible light and light in the near infrared and hardly any light in the ultraviolet. To achieve sufficient energy density in at least one light flash, it can furthermore be advantageous to use a plurality of the mentioned light sources, wherein the light can additionally be bundled, for example, by a suitable reflector onto the surface region to be coated. By way of a sufficiently high energy density in the at least one light flash, in particular the temperature of the surface region to be coated can rise very rapidly, for example, in an order of magnitude of approximately 10⁶ K/s.

As described above, by way of the at least one light flash, the gaseous first starting material can split in particular in the vicinity of the surface region to be irradiated and coated of the electronic component and the material which is to be incorporated in the layer to be applied is thus released. Particularly preferably, the gaseous first starting material can accumulate on the surface region to be coated, i.e., adsorb thereon, before the radiation of the at least one light flash. By way of the at least one light flash and, for example, in particular by way of the above-described rapid and locally bounded strong heating of the surface region, thermal decomposition of the adsorbed molecules of the gaseous first starting material can be achieved. Chemical reactions can thus be activated, so that, for example, reacting off of the first starting material with formation of a monolayer or at least one submonolayer of the layer to be applied on the surface region occurs. Furthermore, the at least one light flash can contribute to material, which is already deposited, of the layer to be applied, being tempered and therefore subjected to so-called annealing, whereby the layer quality can be improved. Therefore, in the case of the light flash ALD method described here, it can also be possible, for example, by supplying only a single gaseous starting material and radiating the at least one light flash, to produce a layer on the surface region, wherein so much energy is supplied by means of the at least one light flash that the starting material can react off on the surface region while forming the layer.

The surface region can particularly preferably be irradiated with a sequence of light flashes. Between the individual light flashes, on the one hand, adsorbed starting material can react off, on the other hand, further starting material can accumulate in a submonolayer or preferably a monolayer on the already absorbed and preferably reacted-off starting material. Therefore, using a sequence of light flashes, preferably one monolayer or at least one submonolayer of the material contained in the starting material can be deposited per light flash for the layer to be applied on the surface region. Good control of the layer thickness of the layer to be deposited can thus be achieved by setting the number of the light flashes radiated onto the surface region.

Furthermore, it can also be possible to use at least one second gaseous starting material, to which the surface region to be coated is subjected after the gaseous first starting material. For this purpose, the second gaseous starting material can be supplied to the surface region after the first gaseous starting material and can be supplied in the absence of the first gaseous starting material. By supplying at least one second starting material, it can be possible, for example, to deposit composite layers, for example, nitrides or oxides, on the at least one surface region of the electronic component. The first gaseous starting material and the second gaseous starting material are preferably supplied alternately to the surface region for this purpose, so that the latter is alternately subjected to the two starting materials. Depending on the starting materials used, the light flashes can be radiated onto the surface region in the presence of one or both starting materials. In particular, the method described here can therefore have a method step in which during the application of the at least one layer by means of the light-flash-assisted atomic layer deposition method, the surface region is subjected to at least one gaseous first starting material or at least one gaseous first starting material and subsequently one gaseous second starting material for the at least one layer, and molecules of the first and/or second starting material adsorbed on the surface region are irradiated with at least one light flash, whereby the molecules adsorbed on the surface region are split. The at least one light flash can therefore be radiated onto the surface region only in the presence of the first starting material or only in the presence of the second starting material. Furthermore, it can also be possible that at least one light flash is radiated onto the surface region to be coated in each case in the presence of each of the starting materials.

Furthermore, it is to be noted that more than two starting compounds can also be used in the method described here.

A starting material, i.e., for example, the gaseous first starting material and/or the gaseous second starting material, can be guided as a gas stream to the surface region to be coated. This can mean that the starting material is supplied into the coating chamber as a continuous gas stream and gaseous residues are continuously removed from the coating chamber. Alternatively thereto, it is also possible to supply a starting material to the coating chamber and therefore to the surface region to be coated before the irradiation by means of the at least one light flash and to stop the gas inflow thereafter, so that no supply and no discharge of the starting material takes place during the at least one light flash.

Flushing steps can also be carried out between the supplies of starting materials and the irradiation by means of light flashes, during which unused starting material and reaction products are discharged. In the method described here, the light flash irradiation, as described above, is carried out during or after the supply of starting materials and in particular before such flushing steps, but not during or directly after such flushing steps, for example, for cleaning the coating chamber.

In addition to a chronologically varying supply of a first and at least one second gaseous starting material by alternating supply, for example various regions of the coating chamber can also be provided, wherein at least the first and the second starting materials are supplied separately from one another into the various regions of the coating chamber. The component to be coated can in particular be movable between the various regions. The various regions can be separated, for example by a gas curtain, for example using an inert gas such as N₂. The component can move continuously or discontinuously in this case, i.e., in steps through the various regions. Depending on whether irradiation of at least one light flash is to be performed in the presence of the first starting material and/or the second starting material, light sources can be provided in the various regions.

According to a further embodiment, the at least one layer is applied in a structured manner. This can mean in particular that the surface region which is coated using the at least one layer by means of light flash ALD only forms a partial region of a coherent surface of the electronic component. After the application of a structured layer, a first part of the surface of the component is therefore covered with the layer without further method steps, while another second region, which can be adjacent to the first region for example, is free of the layer. The surface region to be coated can also comprise in particular noncoherent regions of a surface, for example.

To achieve a structured application of the at least one layer, the at least one light flash can in particular be radiated only onto the surface region to be coated, while surface regions not to be coated are not irradiated with the light flash. For this purpose, the at least one light flash can be radiated onto the electronic component through a mask, for example, wherein the mask has one or more openings over the surface region to be coated. This can mean in particular that the mask is arranged between the surface region and the light source, wherein the mask can have contact to the electronic component or can also be spaced apart from the electronic component, for example. Accordingly, a gaseous starting material can be located above and/or below the mask when seen from the electronic component.

If the surface region to be coated is moved between various regions of the coating chamber, for example to subject the surface region successively to various starting materials, the mask can also be moved with the surface region. Alternatively thereto, it is also possible that a mask remains in a fixed region of the coating chamber. For example, a mask can only be provided and fixedly installed in such a region of the coating chamber in which the at least one light flash is radiated onto the surface region to be coated.

Additionally or alternatively, it can also be possible that the at least one light flash is radiated in a focused manner onto the surface region to be coated or onto a partial region of the surface region to be coated. For this purpose, it can be advantageous in particular if the light source for generating the at least one light flash comprises a laser, for example. It can also be possible in particular to radiate multiple light flashes successively onto various partial regions of the surface region to be coated, so that the creation of the at least one layer on the surface region can be performed sequentially by a coating using monolayers or submonolayers in the partial regions of the surface region. The at least one layer can therefore be applied in a type of laser writing process, for example, in the case of the use of a laser as the light source for the at least one light flash.

In addition to the at least one light flash, which is radiated onto the surface region, heat can be supplied to the surface region to be coated by means of a heater, on which the electronic component to be coated is located, so that the surface region to be coated can additionally be heated. For example, a temperature of less than or equal to 150° C. and preferably less than or equal to 90° C. can be advantageous, at which the typical materials of electronic components, for example organic materials, do not yet take any damage. Alternatively thereto, it can also be possible to cool the electronic component to be coated during the irradiation with the at least one light flash, so that the thinnest possible region of the surface region to be coated is heated by the at least one light flash and material of the electronic component lying under the surface region to be coated can thus be protected from excessively large introduction of heat.

According to a further embodiment, the electronic component, on the surface region of which the at least one layer is applied by means of the light flash ALD method, is an inorganic light-emitting diode (LED), an organic light-emitting diode (OLED), an inorganic photodiode (PD), an organic photodiode (OPD), an inorganic solar cell (SC), an organic solar cell (OSC), an inorganic transistor, in particular an inorganic thin-film transistor (TFT), an organic transistor, in particular an organic thin-film transistor (OTFT), an integrated circuit (IC), or a plurality or combination thereof or can comprise at least one or more of the mentioned components.

The electronic component can furthermore comprise a substrate or can be a substrate. The substrate can be suitable in this case, for example, as a carrier element for electronic elements, in particular one or more optoelectronic layer sequences. For example, the substrate can comprise glass, quartz, and/or a semiconductor material or can consist thereof. Furthermore, the substrate can comprise a plastic film or a laminate having one or more plastic films or a laminate having glass and plastic or can be made thereof. The plastic can comprise or be, for example, high-density and low-density polyethylene (PE), polypropylene (PP), polyvinyl chloride (PVC), polystyrene (PS), polyester, polycarbonate (PC), polyethylene terephthalate (PET), polyether sulfone (PES), and/or polyethylene naphthalate (PEN). Furthermore, the substrate can comprise metal, for example in the form of a metal film, such as an aluminum film, a copper film, a stainless steel film, or a combination or a layer stack thereof.

The electronic component can furthermore comprise a functional layer sequence having at least one first and one second electrode, between which one or more inorganic and/or organic functional layers are arranged. In particular, the functional layer sequence can be arranged on a substrate.

If the electronic component is implemented as an optoelectronic component and comprises, for example, an LED, an OLED, a PD, an OPD, an SC, and/or an OSC or is made thereof, the functional layer sequence can comprise an active region which is capable of generating or detecting light in operation of the component. In particular, the optoelectronic component can also comprise a transparent substrate if light coupling or decoupling is to be performed through the substrate.

If the electronic component comprises an LED, PD, SC, and/or a TFT or is made thereof, the functional layer sequence can comprise an epitaxial layer sequence, i.e., an epitactically grown semiconductor layer sequence, or can be embodied as such. In particular, the semiconductor layer sequence can comprise, for example, a III-V compound semiconductor material based on InGaAlN, InGaAlP, and/or AlGaAs and/or a II-VI compound semiconductor material.

If the electronic component is embodied as an organic electronic component and comprises an OLED, OPD, OSC, and/or an OTFT or is made thereof, the functional layer sequence can comprise one or more organic functional layers having organic polymers, organic oligomers, organic monomers, organic small, non-polymer molecules (“small molecules”), or combinations thereof. In particular, it can be advantageous if an electronic component embodied as an organic electronic component has a functional layer which is embodied as a hole transport layer, for example, in the case of an OLED, to enable effective hole injection into an electroluminescent layer or an electroluminescent region. For example, tertiary amines, carbazole derivatives, conductive polyaniline, or polyethylene dioxythiophene can prove to be advantageous as materials for a hole transport layer. Furthermore, it can be advantageous in the case of an organic optoelectronic component if a functional layer of the functional layer sequence is embodied as a light-generating electroluminescent layer or as a light-detecting layer. Materials which have a light emission because of fluorescence or phosphorescence or which can convert the light into electrical charges are suitable as materials for this purpose, for example polyfluorene, polythiophene, or polyphenylene or derivatives, compounds, mixtures, or copolymers thereof. Furthermore, the functional layer sequence can comprise a functional layer which is implemented as an electron transport layer. In addition, the layer sequence can also comprise electron and/or hole blocking layers.

The electronic component can particularly preferably be implemented as an OLED or comprise an OLED. With regard to the fundamental structure of an OLED, for example, in this case with regard to the structure, the layer composition, and the materials of the functional layer sequence, reference is made to document WO 2010/066245 A1, which is hereby expressly incorporated by reference, in particular with respect to the structure, the layer composition, and the materials of organic optoelectronic components.

During the performance of the light flash ALD method, the electronic component can be finished with regard to its functional layers which provide the functionality of the component, wherein the at least one layer applied by means of the light flash ALD method can in this case, for example, form an encapsulation arrangement or a part of an encapsulation arrangement for the functional layers of the component.

Furthermore, it can additionally or alternatively also be possible that a functional part of the electronic component is produced by means of the light flash ALD, for example an electrical supply line, such as one or more electrical terminal parts, for electrical contacting of an electrode of the electronic component, which is already produced or is still to be produced thereafter. Additionally or alternatively, for example an electrode of a functional layer sequence of an electronic component can be produced by means of the light flash ALD. In these cases, the light flash ALD method can be carried out in each case in a method stage in which the functional layers of the electronic component are not yet finished. In other words, a “production of at least one layer on a surface region of an electronic component” means that the electronic component can already be finished during the performance of the light flash ALD, or that the light flash ALD can be carried out between method steps for producing the electronic component and therefore in the case of an electronic component which is not yet finished. In particular, in this case a functional layer of the electronic component can be produced by means of the light flash ALD method.

According to a further embodiment, at least one electrical supply line for an electrode of the electronic component is implemented on a substrate as at least one layer on a surface region of an electronic component. For this purpose, in particular a metallic layer can be produced by means of light flash ALD, in which a suitable starting material is supplied, which can react off due to the irradiation of the at least one light flash while forming the metallic layer. In comparison to lithographic processes, which are typically used for producing electrical supply lines or conductor webs on substrates, the light flash ALD method described here can enable a simplified mode of production. A layer, which is implemented as a supply line and is applied by means of light flash ALD, can preferably have a thickness of greater than or equal to 100 nm or less than or equal to 1 μm and particularly preferably several hundred nanometers. In particular, the supply line can comprise one or more metals or a layer sequence or a combination thereof or can be made thereof.

According to a further embodiment, at least one electrode of a functional layer sequence of the electronic component is implemented as at least one layer by means of light flash ALD on a surface region of an electronic component. For this purpose, for example, a pure metal, a metal combination, an oxide, a nitride, or combinations or layer sequences thereof can be applied as the electrode. For example, aluminum and/or silver can be applied in the form of a nontransparent electrode. Furthermore, for example silver or a silver mixture, for example silver with magnesium, can be applied as a transparent electrode. The electrode can particularly preferably form a cathode. If the electrode is applied as a metal layer or a metal layer sequence, for example, in particular only one suitable starting material can be supplied, which can react off due to the irradiation of the at least one light flash to form a metallic layer.

Furthermore, an electrode applied by means of light flash ALD can comprise a multilayer structure and/or an alloy in atomic layer size. In addition, for an electrode applied by means of light flash ALD, a multilayer structure having material gradients and/or dopants in atomic layer size can be possible. “In atomic layer size” means in this case that the electrode can comprise layers having the mentioned features, i.e., for example, various layers in a multilayer structure, alloys, material gradients, and/or dopants, which have a thickness of one or a few atomic layers.

Metallic electrodes are typically applied in the prior art by means of thermal vapor deposition or sputtering, because of which the selection of materials and possible modifications for such electrodes, typically cathodes, is restricted. This is because, in the case of the thermal methods, the electrode material typically has to be vapor deposited or sputtered on in high vacuum, since, for example, in the case of organic electronic components, the organic layers on which the electrode is formed react very sensitively to damaging gases and moisture. However, in the case of the typical thermal deposition methods, the high temperature introduction of the sources and, in the case of sputtering processes, the damage due to the plasma used and therefore due to the high energy of the incident material represent a problem.

By way of the light flash ALD method described here, in contrast, in comparison, for example, to thermal vapor deposition methods, a lower temperature stress can result, whereby a greater material selection in the form of pure metals, metal combinations, oxides and nitrides, and possible modifications are possible. Furthermore, the above-mentioned novel structures with respect to the electrode layer structure, material gradients, alloys, and/or dopants can be possible. In this way, it can furthermore be possible to produce denser, injection-optimized electrodes, for example cathodes, and also more transparent electrodes than is possible using typical thermal deposition methods or sputtering methods.

In particular with regard to the production of organic electronic components, it can furthermore be possible that electrode materials directly on organic materials are possible by means of the light flash ALD, since a light flash ALD method, depending on the material to be applied, can be carried out using only one starting material and in particular, for example, without the further starting materials required in the case of typical ALD methods, such as ozone or water, which could damage at least the uppermost organic materials. In comparison to sputtering processes, for example typical sputtering processes for a cathode deposition on organic layers, a light flash ALD method does not result in plasma damage during the deposition on organic materials.

According to a further embodiment, before the application of the at least one layer in the form of an electrode on a functional layer sequence, in particular an organic functional layer sequence, by means of the light flash ALD method, an intermediate layer is applied, which to protect the functional layer sequence from the starting material for the electrode and from undesired light and/or heat introduction.

According to one preferred embodiment, the electronic component comprises a functional layer sequence and the at least one layer is applied by means of light flash ALD as an encapsulation arrangement to the functional layer sequence. For example, the functional layer sequence can comprise at least one light-emitting or light-detecting layer. In this case, the functional layer sequence can particularly preferably form an organic light-emitting diode and can be applied to a substrate as described above.

According to a further embodiment, the at least one layer, which is implemented as an encapsulation arrangement, is applied exclusively to the functional layer sequence. Only the active region of the electronic component, which is sensitive to moisture, can advantageously thus be coated with the at least one layer, while, for example, contacts and other regions of the substrate, onto which no functional layer sequence is applied, remain free of the at least one layer.

According to a further embodiment, the at least one layer, which is applied by means of light flash ALD to the at least one surface region of the electronic component, comprises at least two different layers, i.e., in particular at least two layers having different materials, which are applied as an encapsulation arrangement. In particular, the at least one layer can comprise a layer sequence having alternating layers having different materials.

Therefore, the layer to be applied by means of light flash ALD as an encapsulation arrangement can be applied as a barrier layer or layer sequence having a plurality of barrier layers for producing a thin-film encapsulation. The at least one layer or the plurality of layers can, in the form of an encapsulation arrangement, for example, each have a thickness between one atomic layer and several hundred nanometers, preferably between 10 nm and 100 nm and particularly preferably between 50 nm and 60 nm, wherein the limits of the specified ranges are included.

A thin-film encapsulation is understood in particular as a device which is capable of forming a barrier against atmospheric materials, in particular against moisture, oxygen, and/or against further damaging substances, such as corrosive gases, for example, hydrogen sulfide. Suitable materials for the layers of a thin-film encapsulation are, for example, aluminum oxide, bromine oxide, cadmium sulfide, hafnium oxide, tantalum oxide, titanium oxide, platinum oxide, silicon oxide, vanadium oxide, tin oxide, zinc oxide, zirconium oxide. The encapsulation arrangement applied by means of light flash ALD can comprise, for example, at least two layers made of different materials. In particular, the encapsulation arrangement can also comprise at least three or more layers made of different materials. Furthermore, the encapsulation arrangement can comprise multiple layer stacks one on top of another, each having at least two, three, or more layers made of different materials.

According to a further embodiment, the first gaseous starting material is a metal compound, for example a metal halogen compound or an organometallic compound. For example, the first gaseous starting material can comprise one of the following materials or can be made thereof: trimethyl aluminum (TMA), trimethyl indium (TMIn), trimethyl gallium (TMGa), trimethyl zinc (TMZn), trimethyl tin (TMSn), and ethyl-containing derivatives thereof and also diethyl telluride (DETe), diethyl zinc (DEZn), and tetrabromomethane (CBr₄), BBr₃, Cd(CH₃)₂, Hf[N(Me₂)]₄, Pd(hfac)₂, Pd(hfac)₂, MeCpPtMe₃, MeCpPtMe₃, Si(NCO)₄, SiCl₄, tetrakis(dimethylamino) tin, C₁₂H₂₆N₂Sn, TaCl₅, Ta[N(CH₃)₂]₅, TiCl₄, Ti[OCH(CH₃)]₄, TiCl₄, Zn(CH₂CH₃)₂, (Zr(N(CH₃)₂)₄)₂.

A second gaseous starting material can be provided for forming an oxide, nitride, or sulfide, which comprises one or more of the following materials or is made thereof: H₂O, H₂O₂, H₂, O₂, H₂S, NH₃, and organic compounds and molecules.

Due to the structured application of the at least one layer by means of light flash ALD, it can also be possible that the encapsulation arrangement is implemented having at least two different regions arranged laterally adjacent to one another. In particular, for example, different materials can be applied in a layer plane for this purpose, which have different optical properties. Furthermore, it can also be possible, for example, to apply a first layer of an encapsulation arrangement in a structured manner in a first surface region, while a further layer, which covers the first layer, is applied by means of light flash ALD above it in a second, larger surface region. Due to the use of different materials, which can be arranged laterally adjacent to one another, structures can be introduced into the at least one layer applied by means of light flash ALD, which can be located, for example, above the functional layer sequence of a light-emitting component, in particular an OLED. Due to the use of different materials, for example, in the case of a transparent encapsulation arrangement as at least one layer applied by means of light flash ALD, the light decoupling can be influenced, so that, for example, inscriptions or images such as pictograms are implementable in the illuminated surface, for example in the case of a transparent OLED.

According to a further embodiment, a buffer layer is applied between the surface region to be coated, in particular a functional layer sequence, and the layer to be applied by means of light flash ALD, in particular an encapsulation arrangement. In other words, the buffer layer is thus applied before carrying out the light flash ALD method. The layer to be applied by means of light flash ALD can then subsequently particularly preferably be applied directly on and in direct contact with the buffer layer.

The buffer layer can, for example, form a protective layer from chemical and/or thermal effects for the surface region to be coated. For example, if the surface region to be coated by means of light flash ALD comprises a functional layer sequence, in particular an organic functional layer sequence between two electrodes, one of the electrodes of the functional layer sequence can thus form a top side of the functional layer sequence. If a layer is applied by means of the light flash ALD method directly, i.e., without a buffer layer, to this electrode, which can also be referred to as the top electrode, in the case of a high thermal conductivity of the electrode forming the top side, this can thus result in undesirably high heat introduction into the under the electrode forming the top side during the light flash irradiation. The buffer layer, in contrast, can enable thermal insulation at least to a certain degree, due to which the heat introduction into the layers arranged under the top electrode can be reduced and due to which the layers lying under the top electrode can be protected from excessively large heat stress.

The buffer layer can comprise an oxide, a nitride, or an oxynitride or can be made thereof. For example, the oxide, nitride, or oxynitride can comprise aluminum, silicon, tin, zinc, titanium, zirconium, tantalum, niobium, or hafnium. The buffer layer can particularly preferably comprise silicon nitride (SiₓN_{y}), such as Si₂N₃ and/or silicon oxide (SiOₓ), such as SiO₂. In addition, the buffer layer can also comprise a plurality of layers, for example a sequence of at least one or more silicon nitride layers and one or more silicon oxide layers, which are preferably applied alternately to one another.

The production of the buffer layer can be performed, for example, by means of plasma-enhanced chemical vapor deposition (PECVD). Furthermore, other applications are also possible, for example vapor deposition. The buffer layer can have a thickness of greater than or equal to 10 nm, preferably greater than or equal to several tens of nanometers, in particular greater than or equal to 80 nm. Furthermore, the buffer layer can have a thickness of less than or equal to several hundred nanometers and preferably less than or equal to 400 nm. If the electronic component is a light-emitting component, for example an organic light-emitting diode in which light is decoupled through the layer produced by means of light flash ALD and therefore also through the buffer layer, a thickness in the range of greater than or equal to 80 nm and less than or equal to 100 nm, particularly preferably in the range of greater than or equal to 80 nm and less than or equal to 90 nm, can be particularly advantageous with regard to efficient light decoupling.

By way of the light-flash-assisted atomic layer deposition method described here, because of the material deposition with the aid of the above-described light action and not with the aid of conventional heater heat, it can be possible to use materials, for which high temperatures would be required in conventional atomic layer deposition methods. In the method described here, these materials can be applied at lower temperatures and therefore preferably without negative influence to the electronic components to be coated. Such newly selectable materials can improve the barrier action of at least one layer applied by means of light flash ALD, which is implemented as an encapsulation arrangement, on the one hand, and can also improve, for example, the optical properties, for example, the transparency and the brightness, in particular for transparent electronic components, on the other hand.

Outstanding control of the layer thickness and uniformity is offered due to the self-limiting process. Already applied material can already be tempered or subjected to an annealing process during the deposition of further materials, by a sequence of light flashes, with only slight thermal effect to the electronic component. The application of high-purity thin layers is thus possible. Since only one gaseous starting material can be necessary depending on the material to be applied, a simplification of the conventional ALD methods can result. In particular, if only one starting material is used, undesired reactions with the surface region to be coated, for example, can be avoided. In particular, it can also be possible to apply metal layers, for example as electrical supply lines, by means of the light flash ALD method described here.

The light-flash-assisted atomic layer deposition method described here also enables in particular a structured deposition to be achieved by use of a masking, without complex process steps having to be carried out to remove a layer applied over a large area.

Further advantages, advantageous embodiments, and refinements result from the following exemplary embodiments described in conjunction with the figures.

In the figures:

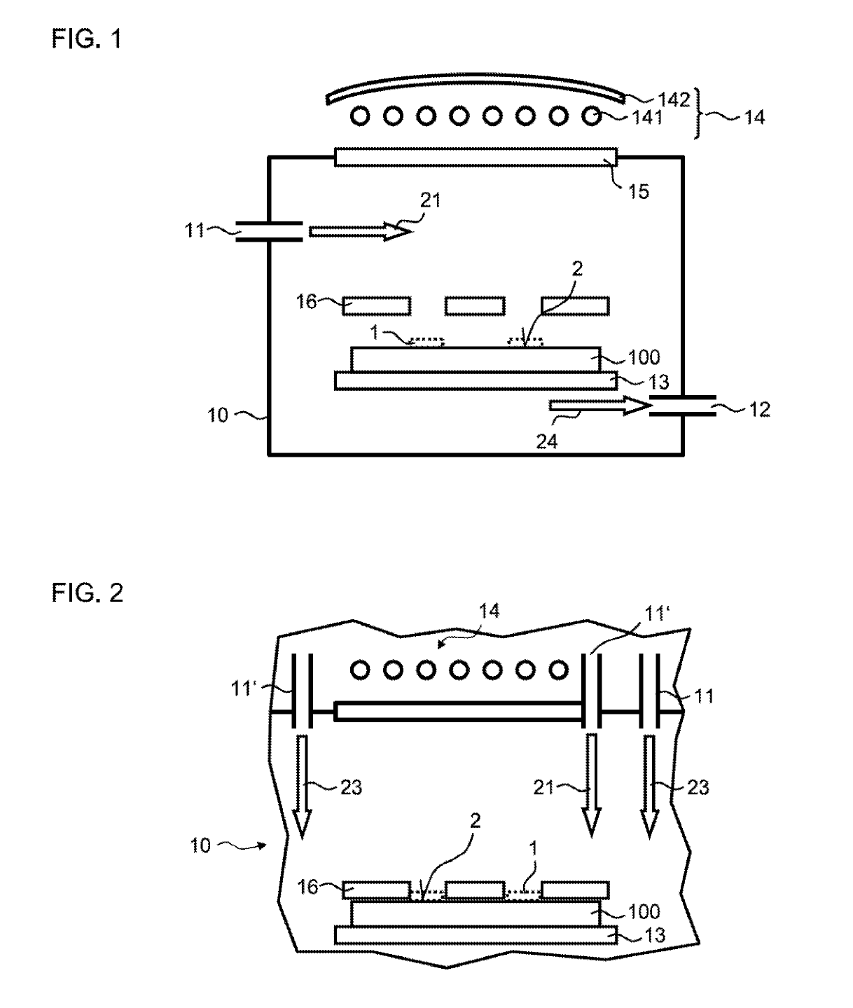

FIG. 1 shows a schematic illustration of a coating chamber for carrying out a method for producing at least one layer on a surface region of an electronic component according to one exemplary embodiment,

FIG. 2 shows a schematic illustration of a coating chamber according to a further exemplary embodiment,

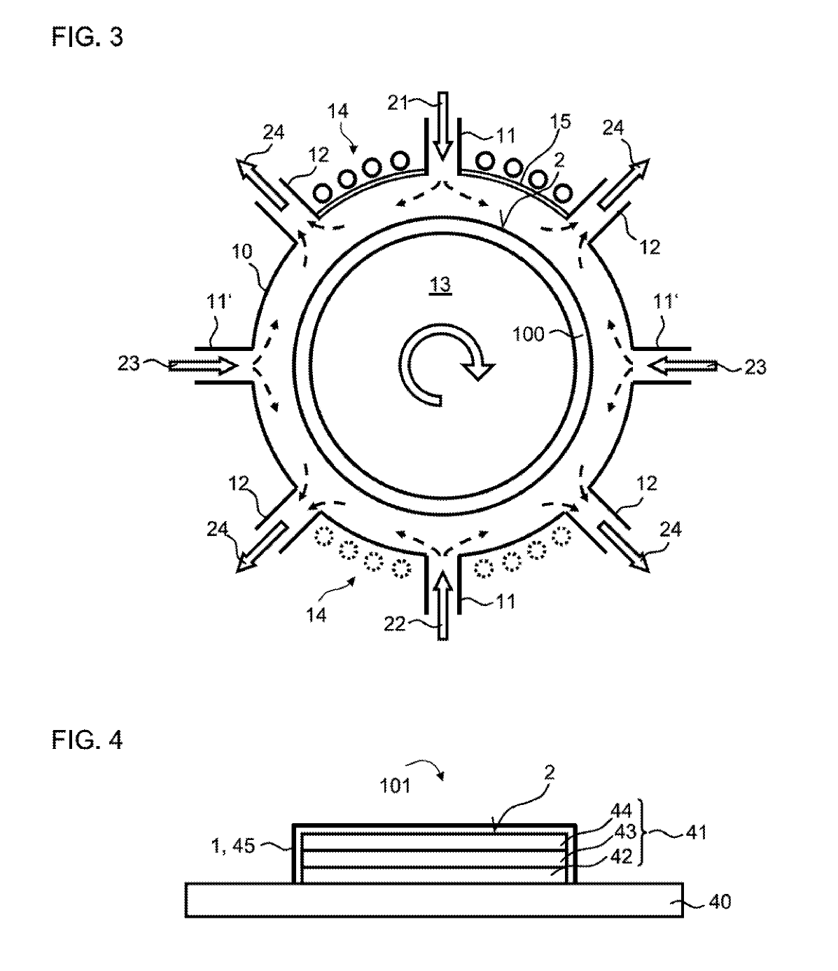

FIG. 3 shows a schematic illustration of a coating chamber according to a further exemplary embodiment,

FIG. 4 shows a schematic illustration of an electronic component which was coated by means of a method for producing at least one layer on a surface region of the electronic component according to a further exemplary embodiment, and

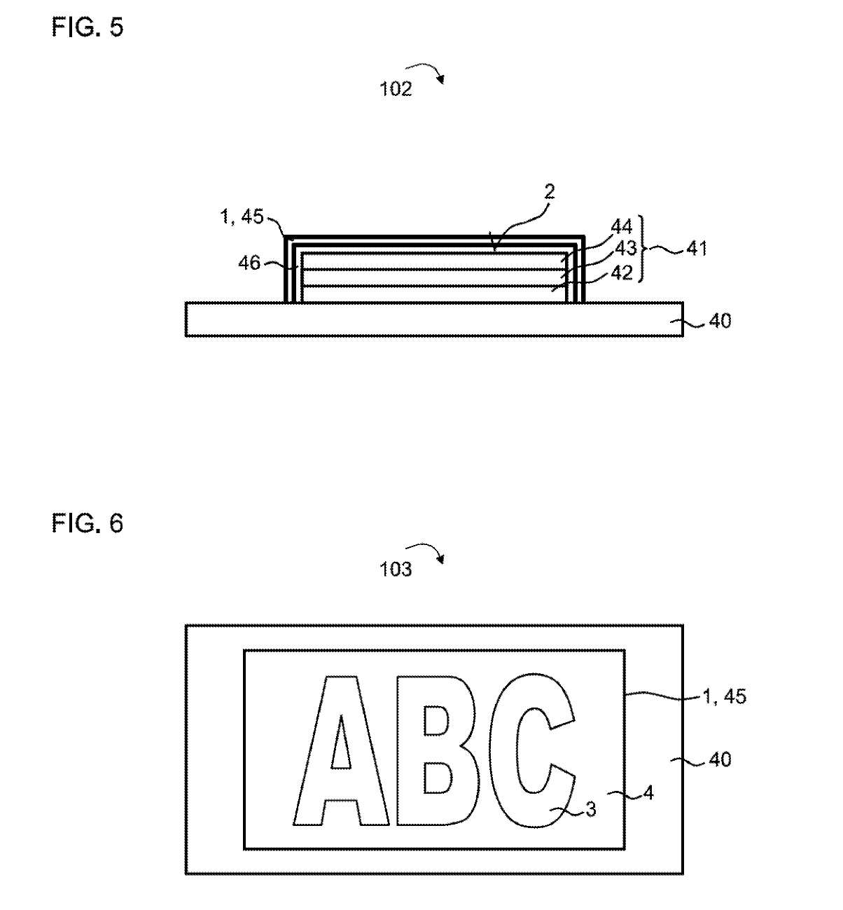

FIGS. 5 to 8 show electronic components which were coated by means of methods for producing at least one layer on a surface region of the components according to further exemplary embodiments.

In the exemplary embodiments and figures, identical, similar, or identically acting elements can each be provided with the same reference signs. The illustrated elements and the size ratios thereof among one another are not to scale, rather individual elements, for example layers, parts, components, and regions, can be shown exaggeratedly large for better presentability and/or for better comprehension.

An exemplary embodiment of a method for producing at least one layer 1 on a surface region 2 of an electronic component 100 is described in conjunction with FIG. 1. For this purpose, a coating chamber 10 is shown in FIG. 1, by means of which the method can be carried out in the form of a light flash ALD method.

In a first method step of the light flash ALD method, the surface region 2 to be coated is provided in the coating chamber 10. For this purpose, the electronic component 100 to be coated, which embodied as described in conjunction with the exemplary embodiments of FIGS. 4 to 7 for example, and can furthermore have alternative or additional features thereto as described above in the general part, is arranged on a carrier 13 in the coating chamber 10. A first gaseous starting material 21 can be supplied to the coating chamber 10 via a gas inlet 11, the starting material containing, in the gas phase, a material of the layer 1 to be applied in the form of chemical compounds, for example organometallic molecules. The exhaust gas arising during the method, which contains gaseous reaction products, for example, can be discharged again from the coating chamber 10 through a gas outlet 12. In particular, the method described in conjunction with FIG. 1 can be operated using a continuous gas inflow of the first gaseous starting material 21.

The first gaseous starting material 21 supplied through the gas inlet 11 can accumulate on the surfaces inside the coating chamber 10 by adsorption, in particular also on the surface region 2 to be coated of the electronic component 100. A light source 14 is arranged outside the coating chamber 10, which can radiate light through a window 15, for example a quartz glass window, into the interior of the coating chamber 10 and in the direction of the electronic component 100 to be coated. In the exemplary embodiment shown, the light source 14 has a plurality of gas discharge lamps 141, the light of which is oriented via a reflector 142 onto the surface region 2 to be coated, and can radiate at least one light flash onto the surface region 2. As described in the general part, in this way heating of the surface region 2 to be coated can be achieved, whereby the molecules of the starting material 21 adsorbed on the surface region 2 can dissociate, so that the material provided for the layer 1, which is contained in the starting material 21 can accumulate on the surface region 2 to be coated and can form compounds thereon. The duration of the at least one light flash and the energy density of the at least one light flash can each have a value mentioned above in the general part and are selected such that the most complete possible layer of the material which is contained in the starting material 21 and provided for the layer 1 can accumulate on the surface region 2 to be coated. A light flash can typically have a duration of several milliseconds, in particular approximately 1 to 2 ms, and an energy density of several J/cm², in particular greater than or equal to 10 J/cm².

As described above in the general part, at least one submonolayer and preferably one monolayer of the desired material contained in the starting material 21 can be applied per light flash. A sequence having a plurality of light flashes is preferably radiated onto the surface region 2 to be coated, wherein easy control of the thickness of the produced layer 1 can be achieved by way of the number of the light flashes.

For example, the first starting material 21 can be trimethyl aluminum, so that aluminum can accumulate as the layer 1 on the surface region 2 of the electronic component 100 due to the light flash action. Alternatively thereto, another starting material described above in the general part can also be used.

In the exemplary embodiment shown, the surface region 2, on which the at least one layer 1 is applied, has, solely as an example, partial regions which are separate from one another and are not coherent. To achieve such a structured application of the at least one layer 1, which is indicated by the dotted regions, the radiation of the at least one light flash of the light source 14 onto the surface region 2 to be coated takes place through a mask 16 which is arranged spaced apart from the surface region 2 in the exemplary embodiment shown. Alternatively thereto, the mask can also be arranged directly on the surface region 2 to be coated, as shown on the bottom FIG. 2.

Alternatively to the described method, which takes place in the gas flow, it can also be possible to supply the gaseous first starting material 21 to the coating chamber 10 before the light flash irradiation, then to close the gas inlet 11 and the gas outlet 12 and to radiate the light flashes into the closed gas volume onto the surface 2 to be coated.

Furthermore, it can also be possible to alternately conduct the first gaseous starting material 21 and at least one second gaseous starting material into the coating chamber 10, for example, to produce an oxide or nitride layer. The first starting material can comprise for this purpose, for example, a metal hydride or an organometallic compound as described above in the general part, while water or ammonia, for example, can be supplied as the second gaseous starting material. A flushing gas, for example a noble gas such as Ar or another inert gas such as N₂, can be supplied between the various starting materials for flushing the coating chamber 10. Depending on the starting materials and the reactivity thereof, a light flash can be radiated onto the surface region 2 only in the presence of the first starting material, only in the presence of the second starting material, or also in the presence of each of the starting materials. For example, the first starting material can be dissociated by a light flash, while the second starting material can then react off with the material of the first starting material accumulated on the surface region 2 without a light flash.

As described in the general part, as much as possible, preferably only the surface region 2, but not layers or materials of the electronic component 100 lying underneath the surface region 2, heats up due to the irradiation of light flashes. If necessary, additional heat energy can be supplied to the electronic component 100 and therefore also to the surface region 2 to be coated, for example, via the carrier 13 by means of a heater. For example, the electronic component 100 can be heated to a temperature of less than or equal to 150° C. and preferably less than or equal to 90° C., while the surface region 2 can be brought to a much higher temperature by the light flash irradiation. Therefore, materials can be applied, the starting materials of which require temperatures which are above those of the electronic component 100, without the electronic component thus being damaged. Alternatively thereto, it can also be possible to actively cool the electronic component 100 by means of a cooling device during the irradiation with the at least one light flash, for example in the carrier 13, to avoid excessively high heating of the electronic component 100 by the light flash irradiation.

Instead of a light source 14 shown in FIG. 1 having gas discharge lamps 141, for example a light source can also be used which comprises one or more lasers, in particular laser diodes, light-emitting diodes, and/or halogen lamps. In particular it can be possible, by means of a laser or also by means of a focused halogen or gas discharge lamp light, to apply the layer 1 to be applied by means of light flash ALD in a structured manner, even without mask 16.

FIG. 2 shows a further exemplary embodiment of a coating chamber 10 in a detail, in which in comparison to the exemplary embodiment of FIG. 1, a first gaseous starting material 21 is supplied over the electronic component 100 to be coated, while adjacent thereto, via further gas inlets 11′, a gas 23, for example N₂, is supplied in the form of a gas curtain. In this way, it can be possible to separate various regions of the coating chamber 10 with regard to the gas distribution, so that in a region of the coating chamber 10 adjacent to the region shown, for example, a second gaseous starting material can be supplied and the various starting materials are separated from one another by gas curtains. The electronic component 100 having the surface region 2 to be coated can be moved back and forth between the various regions, whereby chronologically successive supply of various starting materials into the same region of the coating chamber 10 is not necessary.

The mask 16 can also be moved in this exemplary embodiment, for example, with the surface region 2 to be coated and therefore with the electronic component 100 to be coated. Alternatively thereto, the mask 16 can also be fixedly installed in the region shown of the coating chamber 10 and the electronic component 100 can be moved back and forth between the various regions without the mask 16. The movement of the electronic component 100 can be continuous or also discontinuous in steps in these cases, i.e., in the form of a stop-and-go movement. In particular, the mask 16 can only be present or also moved, for example, in the region or regions of the coating chamber 10 in which light flashes are irradiated onto the surface region 2 to be coated.

FIG. 3 shows a further exemplary embodiment of a coating chamber 10, which enables a so-called roll-to-roll method in comparison to the two previous exemplary embodiments. In this case, the electronic component 100 to be coated is mounted on a roll-shaped carrier 13 which can be rotated as indicated by the circular arrow. A first and a second gaseous starting material 21, 22 can be supplied via gas inlets 11 into a top region and a bottom region of the coating chamber 10. Further gas inlets 11′ are provided between these regions, via which a gas 23 can be supplied, for example N₂ as in the preceding exemplary embodiment, which forms a gas curtain between the various starting materials 21, 22. The gas flows inside the coating chamber 10 are indicated by the dashed lines.

As the first starting material 21, for example, an organometallic compound, for example, trimethyl aluminum or another material mentioned above in the general part can be supplied, which can accumulate on the electronic component 100. By way of the light source 14 arranged in the top region, light flashes can be radiated onto the electronic component 100 via windows 15, so that preferably one monolayer of the metal can be implemented on the surface 2 to be coated per light flash. Due to the rotational movement of the carrier 13, the surface region 2 provided with the adsorbed metal can be moved into the bottom region of the coating chamber 10, into which water, for example, is supplied as the second starting material 22, with which the accumulated aluminum can react to form aluminum oxide. The movement of the electronic component 100 to be coated can be performed continuously or step-by-step. If necessary, depending on the second starting material 22 used, a light source for radiating light flashes can also be provided in the bottom region of the coating chamber 10, as indicated by dotted lines. Further starting materials can additionally be supplied via further gas inlets if necessary.

If a structured implementation of the layer applied by means of light flash ALD is desired, one or more masks can be provided in the coating chamber 10, which can also move with the electronic component 100 or can be arranged in a stationary manner in the top or bottom region of the coating chamber.

The electronic components described hereafter can be coated by means of one of the above-described methods with at least one layer 1 by means of a light flash ALD method.

FIG. 4 shows an electronic component 101 which has a layer 1 which forms an encapsulation arrangement 45 of an electronic component 101 implemented as an organic light-emitting diode (OLED). Alternatively to the OLEDs described in conjunction with FIG. 4 and with the following figures, the electronic component can also be embodied, for example, as an inorganic LED, as an organic or inorganic photodiode, as an organic or inorganic transistor, for example as an organic or inorganic thin-film transistor, or as another electronic component described above in the general part.

The electronic component 101 shown in FIG. 4 has a substrate 40, which can be a glass plate or a glass film, for example. A functional layer sequence 41 having electrodes 42, 44 is arranged on the substrate, between which an organic functional layer sequence 43 having at least one organic light-emitting layer is located. The electronic component 101 can be, for example, a so-called bottom emitter OLED, which emits light through the substrate 40. Alternatively thereto, it can also be a so-called top emitter OLED, which emits light through the encapsulation arrangement 45, or a transparent OLED, which emits light both through the substrate 40 and also in the direction facing away from the substrate 40 through the encapsulation arrangement 45.

The structure of an OLED with respect to the layer structure and the materials of the functional layer sequence 41 is known to a person skilled in the art and will therefore not be explained in greater detail here.

The at least one layer 1 is applied as an encapsulation arrangement 45 to the functional layer sequence 41 by means of the above-described light flash ALD. The functional layer sequence 41 forms for this purpose the surface region 2, to which the at least one layer 1 in the form of the encapsulation arrangement 45 is applied by means of light flash ALD. In particular, the at least one layer 1 is exclusively applied to the functional layer sequence 41, while regions of the substrate 40 which are free of the functional layer sequence 41 are also free of the encapsulation arrangement 45. Therefore, in the electronic component 101 shown here, only the active region, which is sensitive to moisture, in the form of the functional layer sequence 41 is coated, while contacts and supply lines, for example, are free of the encapsulation arrangement 45.

The encapsulation arrangement 45 is embodied in particular as a thin-film encapsulation as described above in the general part. For this purpose, a plurality of layers, for example an alternating sequence of at least two different layers, is applied as at least one layer 1 by means of the above-described light flash ALD method. The layers of the encapsulation arrangement 45 each preferably have a thickness between 50 and 60 nm, wherein the limits are also included. In this case, different layers of the at least one layer 1 can be produced by a corresponding supply of different starting materials successively into a coating chamber, as shown in FIG. 1. Alternatively, it can also be possible, in a coating chamber as described in conjunction with FIGS. 2 and 3, to supply different starting materials into different regions of the coating chamber and to move the electronic component 101 back and forth between these regions in accordance with the desired layer structure.

FIG. 5 shows a further exemplary embodiment, in which, in comparison to the exemplary embodiment of FIG. 4, a buffer layer 46 is arranged between the functional layer sequence 41 and the at least one layer 1 applied by means of light flash ALD, which is implemented as the encapsulation arrangement 45. The encapsulation arrangement 45 is applied in particular directly to the buffer layer 46, wherein the buffer layer 46 can be used as a thermal insulation layer, for example, which prevents excessively large introduction of heat into the functional layer sequence 41 during the light flash ALD method for producing the encapsulation arrangement 45. The buffer layer 46 therefore forms the surface region 2 here, to which the at least one layer 1 is applied in the form of the encapsulation arrangement 45 by means of light flash ALD.

The buffer layer 46, which is applied by means of PECVD in the exemplary embodiment shown, can comprise an oxide, a nitride, or an oxynitride or can be made thereof, in particular can comprise an oxide, nitride, or oxynitride having aluminum, silicon, tin, zinc, titanium, zirconium, tantalum, niobium, or hafnium. The buffer layer 46 can particularly preferably comprise silicon nitride and/or silicon oxide, for example in the form of a single layer or as a layer sequence having at least one or more silicon nitride layers and one or more silicon oxide layers, which are applied alternately one on top of another. The buffer layer 46 has a thickness in a range of several tens of nanometers and several hundred nanometers, preferably in the range of approximately 400 nm in the case of a bottom emitter OLED and in the range of greater than or equal to 80 nm and less than or equal to 90 nm in the case of a top emitter OLED or a transparent OLED as the electronic component 102.

FIG. 6 shows a further exemplary embodiment of an electronic component 103 in a top view, which has a layer 1, which is implemented as an encapsulation arrangement 45 and is applied by means of light flash ALD, and which has two different regions 3, 4 arranged laterally adjacent to one another. The different regions 3, 4 comprise different materials which have different optical properties and therefore enable structured light decoupling from the electronic component 103. The appearance of the electronic component 103, which can be implemented as a transparent OLED, for example, can be influenced in the activated and/or deactivated state by the structure thus achieved in the illuminated surface of the electronic component 103, so that an inscription is implementable in the illuminated surface as shown in FIG. 6, for example.

To produce the regions 3, 4, one or more layers are deposited in one of the regions 3, 4 by means of light flash ALD. Subsequently, one or more other layers are deposited by means of light flash ALD in another of the regions 3, 4, wherein the entirety of the layers in the regions 3 and 4 forms the at least one layer 1 produced by means of light flash ALD. Alternatively, it is also possible to deposit one or more layers in one of the regions 3, 4 by means of light flash ALD and subsequently to provide both regions 3, 4 jointly with one or more layers by means of light flash ALD, so that the number of the layers are different in the regions 3, 4.

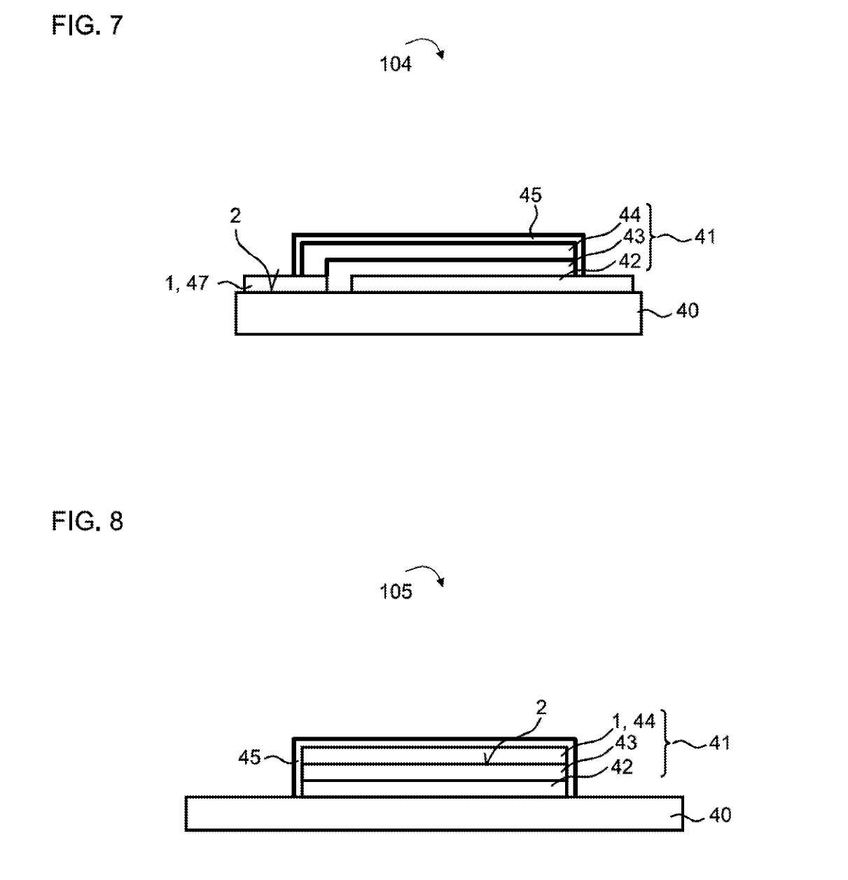

FIG. 7 shows a further electronic component 104 which comprises at least one supply line 47 for one of the electrodes 44, which is formed by at least one layer 1, which is applied by means of light flash ALD, on one surface region 2 of the electronic component 104.

The supply line 47, which is implemented as an electrical terminal layer for the top electrode 44 and contacts the latter, is produced as a metallic layer by means of light flash ALD, wherein a suitable starting material, for example, TMA, is supplied, which can react off due to the irradiation of the at least one light flash while forming a metallic layer, for example an aluminum-containing layer. Alternatively or additionally, other materials are also possible as described above in the general part.

The layer 1, which is implemented as a supply line 47 and is applied by means of light flash ALD, preferably has a thickness of greater than or equal to 100 nm or less than or equal to 1 μm and particularly preferably several hundred nanometers. By way of the light flash ALD method, complex lithographic processes, which are typically used to produce electrical supply lines on substrates, can be avoided.

Furthermore, it can also be possible that the encapsulation arrangement 45 is also deposited by means of light flash ALD as in the preceding exemplary embodiments.

FIG. 8 shows an electronic component 105 according to a further exemplary embodiment, in which a layer 1 in the form of an electrode 44, for example, a cathode, of a functional layer sequence 41 is applied by means of a light flash ALD method. For this purpose, the uppermost layer of the organic functional layer sequence 43 forms the surface region to which the at least one layer 1 is applied in the form of the electrode 44.

The electrode 44 can comprise, for example, a pure metal, a metal combination, an oxide, a nitride, or combinations or layer sequences thereof and can be transparent or nontransparent. For example, aluminum and/or silver can be applied in the form of a nontransparent electrode 44. Furthermore, for example, silver or a silver mixture, for example silver with magnesium, can be applied as the transparent electrode 44. If the electrode is applied, for example, as a metallic layer or a metallic layer sequence, in particular only a first gaseous starting material, for example, TMA for an aluminum electrode, can be supplied, which can react off to form a metallic layer due to the irradiation of the at least one light flash.

The electrode 44 can furthermore also comprise a multilayer structure and/or an alloy in atomic layer size. In addition, the electrode can comprise a multilayer structure having material gradients and/or dopants in atomic layer size.

The electrode 44 can be applied over a large area and coherently, i.e., in particular in an unstructured manner. In addition, it can also be possible that the electrode 44 is applied in a structured manner by means of the light flash ALD method, so that the electronic component 105 can provide a spatially and/or chronologically varying light impression, for example. Before the application of the electrode 44 to the organic functional layer sequence 43 by means of the light flash ALD method, an intermediate layer can also be applied as described above in the general part, to protect the organic functional layer sequence 43 from the starting material for the electrode 44 and from undesired introduction of light and/or heat.

Furthermore, it can also be possible that the encapsulation arrangement 45 is also deposited as in the preceding exemplary embodiments by means of light flash ALD. In addition, at least one supply line can also be provided as an electrical terminal element for the electrode 44, which can be applied as in the preceding exemplary embodiment by means of light flash ALD.

The exemplary embodiments shown in conjunction with the figures and the individual features thereof can be combined with one another in further exemplary embodiments which are not explicitly shown. Furthermore, the exemplary embodiments shown in the figures can have alternative or additional features according to the embodiments in the general part.

The invention is not restricted thereto by the description on the basis of the exemplary embodiments. Rather, the invention comprises every novel feature and every combination of features which includes in particular every combination of features in the patent claims, even if this feature or this combination itself is not explicitly specified in the patent claims or exemplary embodiments.

1. A method for producing at least one layer on a surface region of an optoelectronic component which comprises a functional layer sequence having an active region which is capable of generating or detecting light in operation of the optoelectronic component, having the following steps:
providing the surface region in a coating chamber,
applying the at least one layer by means of a light-flash-assisted atomic layer deposition method, wherein the surface region is subjected to at least one gaseous first starting material or at least one gaseous first starting material and subsequently one gaseous second starting material for the at least one layer, and molecules of the first and/or second starting material adsorbed on the surface region are irradiated with at least one light flash, whereby the molecules adsorbed on the surface region are split.

2. The method according to claim 1, wherein the at least one light flash is supplied by means of a light source which comprises at least one selected from the following: gas discharge lamp, halogen lamp, laser, light-emitting diode.

3. The method according to claim 1, wherein the surface region is irradiated with a sequence of light flashes.

4. The method according to claim 1, wherein the at least one layer is applied in a structured manner.

5. The method according to claim 4, wherein the at least one light flash is radiated through a mask onto the surface region.

6. The method according to claim 4, wherein the at least one light flash is radiated in a focused manner onto a partial region of the surface region.

7. The method according to claim 4, wherein multiple light flashes are radiated successively onto various partial regions of the surface region.

8. The method according to claim 1, wherein the surface region is alternately subjected to the first gaseous starting material and at least one second gaseous starting material.

9. The method according to claim 8, wherein light flashes are radiated onto the surface region only in the presence of the first starting material or only in the presence of the second starting material.

10. The method according to claim 8, wherein at least the first and second starting materials are supplied into various regions of the coating chamber and the component is movable between the various regions.

11. The method according to claim 10, wherein the various regions are separated by a gas curtain using an inert gas.

12. The method according to claim 1, wherein the electronic component is cooled during the irradiation with the at least one light flash.

13. The method according to claim 1, wherein the functional layer sequence forms an organic light-emitting diode and is applied to a substrate.

14. The method according to claim 1, wherein the at least one layer is implemented as at least one electrical supply line for an electrode of the functional layer sequence on a substrate.

15. The method according to claim 1, wherein the at least one layer is implemented as an electrode of the functional layer sequence.

16. The method according to claim 1, wherein the at least one layer is applied as an encapsulation arrangement to the functional layer sequence.

17. The method according to claim 16, wherein a buffer layer is applied between the functional layer sequence and the encapsulation arrangement.

18. The method according to claim 16, wherein the encapsulation arrangement is applied exclusively to the functional layer sequence.

19. The method according to claim 16, wherein at least two different layers are applied by means of the light-flash-assisted atomic layer deposition method as the encapsulation arrangement.

20. The method according to claim 16, wherein the encapsulation arrangement is implemented having at least two different regions arranged laterally adjacent to one another by means of the light-flash-assisted atomic layer deposition method.
